(19) United States
(12) Patent Application Publication
(10) Pub. No.: US 2020/0005983 A1
(43) Pub. Date: Jan. 2, 2020

(54) MAGNETIC ENCAPSULANT FOR PACKAGE MAGNETIC INDUCTORS

(71) Applicant: Intel Corporation, Santa Clara, CA (US)

(72) Inventors: Malavarayan SANKARASUBRAMANIAN, Chandler, AZ (US); Yongki MIN, Phoenix, AZ (US); Anne AUGUSTINE, Chandler, AZ (US); Kaladhar RADHAKRISHNAN, Chandler, AZ (US); Taylor GAINES, Chandler, AZ (US); Ziyin LIN, Chandler, AZ (US)

(21) Appl. No.: 16/024,718

(22) Filed: Jun. 29, 2018

(51) Int. Cl. H01F 27/02; H01F 1/42; H01F 41/00; H01F 1/01; H01L 25/16; H01L 21/48; H01F 27/29

(52) U.S. Cl. CPC H01F 27/022; H01F 1/42; H01F 41/005; H01L 23/49822; H01L 25/16; H01L 21/4853; H01F 27/292; H01F 1/01

(57) ABSTRACT

Embodiments herein relate to a magnetic encapsulant composite, comprising a mixture of a first material that is a soft magnetic filler, a second material that is a polymer matrix, and a third material that is a process ingredient. The magnetic encapsulant composite may then encapsulate or partially encapsulate a magnetic inductor coupled to a substrate to increase the inductance of the magnetic inductor and/or to strengthen the substrate to which the magnetic inductor and the composite are coupled.

### FIELD

Embodiments of the present disclosure generally relate to the field of package assemblies, and in particular package assemblies that include inductors.

### BACKGROUND

The background description provided herein is for the purpose of generally presenting the context of the disclosure. Unless otherwise indicated herein, the materials described in this section are not prior art to the claims in this application and are not admitted to be prior art by inclusion in this section.

Continued reduction in end product size of mobile electronic devices such as smart phones and ultrabooks is a driving force for the development of reduced size system in package components.

### BRIEF DESCRIPTION OF THE DRAWINGS

FIG. 1 illustrates examples of a package assembly with a magnetic inductor coupled with a side of the package and encapsulated in a magnetic encapsulant, in accordance with embodiments of the present invention.

FIG. 2 illustrates an example of a process for manufacturing a package assembly, in accordance with an embodiment of the present invention.

FIG. 3 is a schematic of a computer system, in accordance with an embodiment of the present invention.

### DETAILED DESCRIPTION

Embodiments of the present disclosure may generally relate to encapsulating magnetic inductor with a magnetic encapsulant material, which may also be referred to as a magnetic encapsulant composite, in order to improve inductor electrical performance, reliability, and structural stability for a component, for example a substrate of a package, to which the magnetic inductor may be coupled.

As the area available to design package inductors, or air core inductors (ACIs), on integrated circuit (IC) packages is decreasing. There is an increased use of discrete inductors, such as magnetic inductor arrays (MIA), that may be coupled with IC packages, for example on the land side of a package or on some other side. In legacy implementations, these magnetic inductors given their thickness may have required removal of a portion of a printed circuit board (PCB) or other surface to which the package may be coupled due to the thickness of the magnetic inductor.

Recently, thinner MIAs have become available, and may be coupled to packages. In embodiments described herein, encapsulating these MIAs, or other magnetic inductors, partially or fully within a magnetic encapsulant material may allow these thinner MIAs be used and to function at a similar or greater performance level than thicker MIAs. In addition, the magnetic encapsulant may also provide additional support to the MIAs or other magnetic inductors to prevent them from cracking or failing when they are attached to high-warpage packages. The magnetic encapsulant as a result may decrease package reliability failures.

In embodiments, MIA as a standalone component, which may be a plan of record (POR) solution for packages, may be fully or partially encapsulated by a magnetic encapsulant. In embodiments, particularly with respect to legacy implementations, MIA height may be reduced to accommodate the smaller stand-off height for landside components of the package. This reduction in height of the MIA may result in reduced inductance and overall quality factor (Q factor) of the MIA. Additionally, stresses on the vias, in particular copper (Cu) vias, and solder joints proximate to the MIA may be quite high during temperature cycling. This may result in reliability failures for the packages.

In embodiments, fully or partially encapsulating a magnetic inductor in encapsulant may reduce stress on solder and/or vias that may be used coupling the magnetic inductor to a substrate or a package. This may reduce overall defect rates of the substrate or package.

In embodiments, the magnetic encapsulants may contain soft magnetic fillers and may provide additional magnetic energy in addition to the inductor component. As a result, this may increase the performance and/or inductance of the component while maintaining the overall volume and/or footprint of the component.

In legacy implementations, discrete inductors may be used as land side components. With reductions in the second level interconnect (SLI) solder ball height and/or removal of a recess in the motherboard to accommodate discreet inductors, thinner, more reliable, and higher performance inductors may be accommodated. In embodiments, magnetic encapsulants may enable thinner inductors with improved reliability and power delivery performance.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

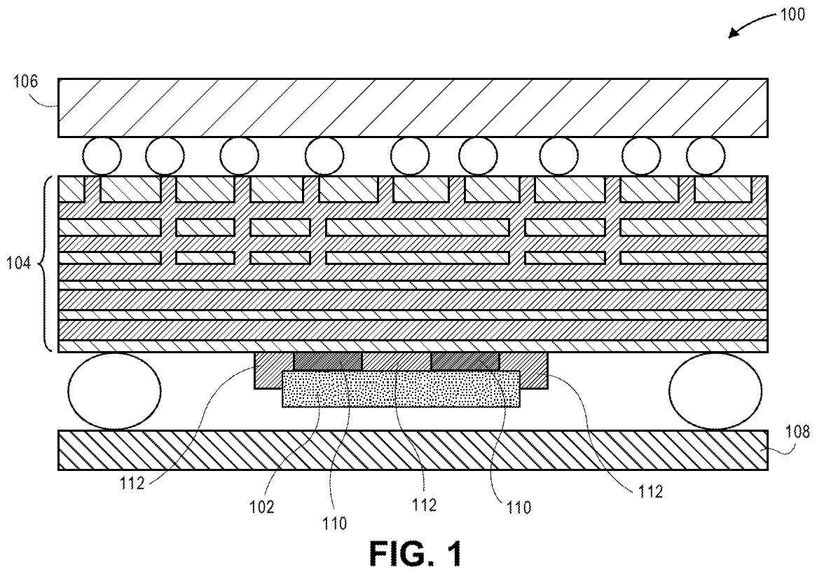

FIG. 1 illustrates examples of a package assembly with a magnetic inductor coupled with a side of the package and encapsulated in a magnetic encapsulant, in accordance with embodiments of the present invention. Diagram 100 may show an IC package that includes a magnetic inductor 102 that is coupled with one side of a package body 104. In embodiments, the package body 104 may be coupled with a die 106 and with the substrate 108, such as a PCB substrate. In embodiments, the package body 104 may be any surface or other component that may make up an IC package similar to diagram 100.

In embodiments, the magnetic inductor 102 may be coupled to the package body 104 by solder joints 110. In embodiments, the solder joints 110 may be any other material or component that may be used to adhere the inductor 102 to the package body 104.

In embodiments, a magnetic encapsulant material 112 may encapsulate all or part of the inductor 102. In embodiments, the magnetic encapsulant material 112 may also encapsulate the solder joints 110 and/or other portions of the package body 104. As shown in FIG. 1, the magnetic encapsulant material 112 only encapsulates a portion of the inductor 102. In other embodiments (not shown), the magnetic encapsulant material 112 may completely surround the inductor 102. In embodiments, the inductor 102 may be multiple inductors or may include other components.

In embodiments, the package body 104 to which the inductor 102 may be attached may take a variety of forms. For example, the package body 104 may be a coreless package (as shown). The package body 104 may have a package core (not shown), that may include multiple vias through the core to electrically couple the inductor 102 with any portion of the package body 104.

In embodiments, the composition of the magnetic encapsulant may include (1) magnetic fillers, and (2) polymers and/or processing aids. Magnetic fillers may include at least one of a metallic magnetic material or a soft ferrite magnetic material. In embodiments, the metallic magnetic material may include, but is not limited to, Fe, oriented FeSi, unoriented FeSi, FeNi, FeCo, FeSiBNbCu, and/or CoZrTa. In embodiments, the composition of the metallic magnetic material may be tailored based upon the implementation requirements of the magnetic encapsulant. For example, if the magnetic encapsulant is to primarily enhance the performance of the inductor 102, or is primarily to provide structural reinforcement to the solder joints 110.

In embodiments, soft ferrite magnetic material may include, but are not limited to, MnZn, NiZn, and/or Fe₂O₃. As described above, the composition of the soft ferrite magnetic material may be tailored based upon the implementation requirements of the magnetic encapsulant.

In embodiments, a polymer component and/or processing aids may include resins, catalysts, initiators, polymers, toughening agents, surfactants, adhesion promotors, thixotropic index modifiers, reactive diluents, or other process enabling or property modifiers. polymer component of the formulation may include systems such as acrylates (e.g., methacrylate), epoxies (e.g., bis-A, bis-F), urethanes, cyano-acrylates, cyano-urethanes, silicones (e.g., polysiloxane) or mixtures thereof. In embodiments, the encapsulant material may be curable by hardeners, catalysts, cationic, nucleophilic or ultraviolet (UV) initiators or a combination thereof.

In embodiments, initiator systems might include acids, bases such as carboxylic acids or amines, respectively; peroxides; and/or any photo initiator such as azobisisobutyronitrile. The composition of the polymers and/or processing aids may be tailored based upon the implementation requirements of the magnetic encapsulant.

In embodiments, adding the magnetic material as described above to the magnetic encapsulant material 112 may cause the magnetic encapsulant material 112 to store additional magnetic energy during operation of the inductor 102. As a result, the resulting inductance may increase and result in an improvement in the inductor Q factor. This may result in an improvement in ripple, power loss, and/or efficiency for the power provided by the inductor 102 to the package body 104 and/or the die 106. In embodiments, the performance of the inductor 102 fully or partially embedded within magnetic encapsulant material 112 may be the same as or better than a larger inductor that is not fully or partially embedded within magnetic encapsulant material 112. As a result, in embodiments an inductor 102 may be used where there is a smaller gap between the package body 104 and the substrate 108. As an example, a thinner magnetic inductor 102, such as a thinner MIA. In embodiments, portions (not shown) of the substrate 108 may not need to be etched out or removed to accommodate the thickness of the magnetic inductor 102.

In embodiments, the magnetic encapsulant material 112 may completely surround the solder joints 110 to reduce stress on the solder joints 110 (or other connectivity mechanism) that connect the package body 104 to the inductor 102. When cured, the magnetic encapsulant material 112 may provide additional support for the solder joints 110 and the inductor 102, particularly when all or part of the substrate package body 104 may be subject to thermal mechanical stresses and/or warpages. This, in turn, may cause thermal mechanical stresses on the solder joints 110, which may cause them to crack or otherwise fail. Thermal mechanical stresses may also be transferred to the magnetic inductor 102, which may cause damage to the inductor 102 and shorten its useful life. As discussed above, selecting various materials going into the magnetic encapsulant material 112 may result in varying structural properties of the magnetic encapsulant material 112 when it is cured. The encapsulant materials can be tailored with different polymer matrixes, varied filler content, distribution and packing density. In addition, the encapsulant material can also contain additives both organic and inorganic to increase the facilitate the manufacturing process and/or to increase damping capacity of the encapsulant.

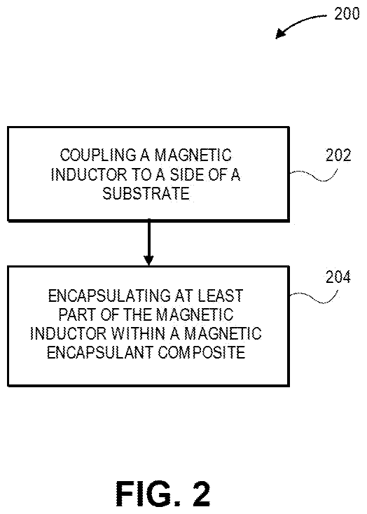

FIG. 2 illustrates an example of a process for manufacturing a package assembly, in accordance with an embodiment of the present invention. In embodiments, process 200 may be performed by one or more of the techniques, processes, or actions described with respect to FIG. 1.

At block 202, the process may include coupling a magnetic inductor to a side of a substrate. In embodiments, the magnetic inductor may be similar to magnetic inductor 102, and the substrate may be similar to package body 104. The magnetic inductor 102 may be coupled to the package body 104 by solder joints 110, or by some other coupling mechanism, as described above.

At block 204, the process may include encapsulating at least part of the magnetic inductor within a magnetic encapsulant composite. In embodiments, the magnetic encapsulant composite may be similar to the magnetic encapsulant material 112. In embodiments the composition of the magnetic encapsulant material 112 may be as described above.

This process may also include encapsulating all or part of the solder joints 110 in the magnetic encapsulant material 112. Magnetic filler within the magnetic encapsulant material 112 may provide additional structural support for solder joints 110, particularly if the package body is subject to warping, for example due to extreme temperature swings during operation.

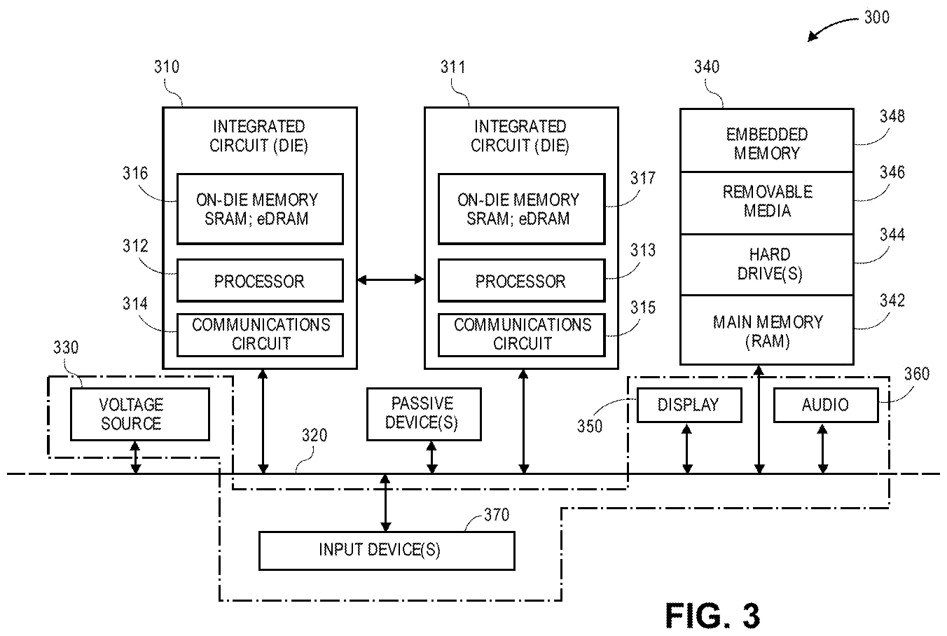

FIG. 3 is a schematic of a computer system 300, in accordance with an embodiment of the present invention. The computer system 300 (also referred to as the electronic system 300) as depicted can embody a magnetic encapsulant for magnetic inductors, according to any of the several disclosed embodiments and their equivalents as set forth in this disclosure. The computer system 300 may be a mobile device such as a netbook computer. The computer system 300 may be a mobile device such as a wireless smart phone. The computer system 300 may be a desktop computer. The computer system 300 may be a hand-held reader. The computer system 300 may be a server system. The computer system 300 may be a supercomputer or high-performance computing system.

In an embodiment, the electronic system 300 is a computer system that includes a system bus 320 to electrically couple the various components of the electronic system 300. The system bus 320 is a single bus or any combination of busses according to various embodiments. The electronic system 300 includes a voltage source 330 that provides power to the integrated circuit 310. In some embodiments, the voltage source 330 supplies current to the integrated circuit 310 through the system bus 320.

The integrated circuit 310 is electrically coupled to the system bus 320 and includes any circuit, or combination of circuits according to an embodiment. In an embodiment, the integrated circuit 310 includes a processor 312 that can be of any type. As used herein, the processor 312 may mean any type of circuit such as, but not limited to, a microprocessor, a microcontroller, a graphics processor, a digital signal processor, or another processor. In an embodiment, the processor 312 includes, or is coupled with a magnetic encapsulant for magnetic inductors, as disclosed herein. In an embodiment, SRAM embodiments are found in memory caches of the processor. Other types of circuits that can be included in the integrated circuit 310 are a custom circuit or an application-specific integrated circuit (ASIC), such as a communications circuit 314 for use in wireless devices such as cellular telephones, smart phones, pagers, portable computers, two-way radios, and similar electronic systems, or a communications circuit for servers. In an embodiment, the integrated circuit 310 includes on-die memory 316 such as static random-access memory (SRAM). In an embodiment, the integrated circuit 310 includes embedded on-die memory 316 such as embedded dynamic random-access memory (eDRAM).

In an embodiment, the integrated circuit 310 is complemented with a subsequent integrated circuit 311. Useful embodiments include a dual processor 313 and a dual communications circuit 315 and dual on-die memory 317 such as SRAM. In an embodiment, the dual integrated circuit 310 includes embedded on-die memory 317 such as eDRAM.

In an embodiment, the electronic system 300 also includes an external memory 340 that in turn may include one or more memory elements suitable to the particular application, such as a main memory 342 in the form of RAM, one or more hard drives 344, and/or one or more drives that handle removable media 346, such as diskettes, compact disks (CDs), digital variable disks (DVDs), flash memory drives, and other removable media known in the art. The external memory 340 may also be embedded memory 348 such as the first die in a die stack, according to an embodiment.

In an embodiment, the electronic system 300 also includes a display device 350, an audio output 360. In an embodiment, the electronic system 300 includes an input device such as a controller 370 that may be a keyboard, mouse, trackball, game controller, microphone, voice-recognition device, or any other input device that inputs information into the electronic system 300. In an embodiment, an input device 370 is a camera. In an embodiment, an input device 370 is a digital sound recorder. In an embodiment, an input device 370 is a camera and a digital sound recorder.

As shown herein, the integrated circuit 310 can be implemented in a number of different embodiments, including a package substrate having a magnetic encapsulant for magnetic inductors, according to any of the several disclosed embodiments and their equivalents, an electronic system, a computer system, one or more methods of fabricating an integrated circuit, and one or more methods of fabricating an electronic assembly that includes a package substrate having a magnetic encapsulant for magnetic inductors, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having a magnetic encapsulant for magnetic inductors embodiments and their equivalents. A foundation substrate may be included, as represented by the dashed line of FIG. 3. Passive devices may also be included, as is also depicted in FIG. 3.

The following paragraphs describe examples of various embodiments.

Example 1 may be a magnetic encapsulant composite, comprising a mixture of: a first material that is a soft magnetic filler; a second material that is a polymer matrix; and a third material that is a process ingredient.

Example 2 may include the magnetic encapsulant composite of example 1, wherein the first material includes at least a selected one of: a metallic magnetic material or a soft ferrite magnetic material.

Example 3 may include the magnetic encapsulant composite of example 2, wherein the metallic magnetic material includes at least a selected one of: Fe, oriented FeSi, unoriented FeSi, FeNi, FeCo, FeSiBNbCu, or CoZrTa.

Example 4 may include the magnetic encapsulant composite of example 2, wherein the soft ferrite magnetic material includes at least a selected one of: MnZn, NiZn, or Fe2O3.

Example 5 may include the magnetic encapsulant composite of example 1, wherein the second material includes at least a selected one of: an acrylate, a methacrylate, an epoxy, a urethane, a cyano-acrylate, a cyano-urethane, or a silicone.

Example 6 may include the magnetic encapsulant composite of example 1, wherein the third material includes at least a selected one of: a resin, a catalyst, an initiator, a polymer, a toughening agent, a surfactant, an adhesion promotor, a thixotropic index modifier, or a reactive diluent.

Example 7 may include the magnetic encapsulant composite of example 1, wherein the composite is to be cured by at least a selected one of: a hardener, a catalyst, a cationic, a nucleophilic, or an ultraviolet (UV) initiator.

Example 8 may include the magnetic encapsulant composite of example 1, wherein the composite is to encapsulate or to partially encapsulate a magnetic inductor coupled to a substrate to increase the inductance of the magnetic inductor.

Example 9 may include the magnetic encapsulant composite of example 8, wherein the composite is further to strengthen the substrate to which the magnetic inductor and the composite are coupled.

Example 10 may be a method, comprising: coupling a magnetic inductor to a side of a substrate; and encapsulating at least part of the magnetic inductor within a magnetic encapsulant composite.

Example 11 may include the method of example 10, wherein coupling the magnetic inductor with the side of the substrate further includes soldering the magnetic inductor to the side of the substrate.

Example 12 may include the method of example 11, further comprising encapsulating at least a part of a solder joint within the magnetic encapsulant composite.

Example 13 may include the method of example 11, wherein the magnetic encapsulant composite includes a soft magnetic filler, a polymer matrix, and a process ingredient.

Example 14 may be a package comprising: a substrate; a magnetic inductor coupled with a side of the substrate; and a magnetic encapsulant composite coupled to the magnetic inductor.

Example 15 may include the package of example 14, wherein the magnetic encapsulant composite partially encapsulates or fully encapsulates the magnetic inductor to increase the inductance of the magnetic inductor.

Example 16 may include the package of example 14, wherein the magnetic inductor is coupled to the side of the substrate with a solder joint.

Example 17 may include the package of example 16, wherein the magnetic encapsulant composite fully encapsulates the solder joint.

Example 18 may include the package of example 14, wherein the magnetic encapsulant composite is coupled to the side of the substrate to strengthen the side of the substrate.

Example 19 may include the package of example 14, wherein the side of the substrate is a first side of the substrate with a second side opposite the first side; and wherein the second side of the substrate is to couple with a die.

Example 20 may include the package of example 19, wherein the package includes the die.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. A magnetic encapsulant composite, comprising a mixture of:
a first material that is a soft magnetic filler;
a second material that is a polymer matrix; and
a third material that is a process ingredient.

2. The magnetic encapsulant composite of claim 1, wherein the first material includes at least a selected one of: a metallic magnetic material or a soft ferrite magnetic material.

3. The magnetic encapsulant composite of claim 2, wherein the metallic magnetic material includes at least a selected one of: Fe, oriented FeSi, unoriented FeSi, FeNi, FeCo, FeSiBNbCu, or CoZrTa.

4. The magnetic encapsulant composite of claim 2, wherein the soft ferrite magnetic material includes at least a selected one of: MnZn, NiZn, or Fe₂O₃.

5. The magnetic encapsulant composite of claim 1, wherein the second material includes at least a selected one of: an acrylate, a methacrylate, an epoxy, a urethane, a cyano-acrylate, a cyano-urethane, or a silicone.

6. The magnetic encapsulant composite of claim 1, wherein the third material includes at least a selected one of: a resin, a catalyst, an initiator, a polymer, a toughening agent, a surfactant, an adhesion promotor, a thixotropic index modifier, or a reactive diluent.

7. The magnetic encapsulant composite of claim 1, wherein the composite is to be cured by at least a selected one of: a hardener, a catalyst, a cationic, a nucleophilic, or an ultraviolet (UV) initiator.

8. The magnetic encapsulant composite of claim 1, wherein the composite is to encapsulate or to partially encapsulate a magnetic inductor coupled to a substrate to increase the inductance of the magnetic inductor.

9. The magnetic encapsulant composite of claim 8, wherein the composite is further to strengthen the substrate to which the magnetic inductor and the composite are coupled.

10. A method, comprising:
coupling a magnetic inductor to a side of a substrate; and
encapsulating at least part of the magnetic inductor within a magnetic encapsulant composite.

11. The method of claim 10, wherein coupling the magnetic inductor with the side of the substrate further includes soldering the magnetic inductor to the side of the substrate.

12. The method of claim 11, further comprising encapsulating at least a part of a solder joint within the magnetic encapsulant composite.

13. The method of claim 11, wherein the magnetic encapsulant composite includes a soft magnetic filler, a polymer matrix, and a process ingredient.

14. A package comprising:
a substrate;
a magnetic inductor coupled with a side of the substrate; and
a magnetic encapsulant composite coupled to the magnetic inductor.

15. The package of claim 14, wherein the magnetic encapsulant composite partially encapsulates or fully encapsulates the magnetic inductor to increase the inductance of the magnetic inductor.

16. The package of claim 14, wherein the magnetic inductor is coupled to the side of the substrate with a solder joint.

17. The package of claim 16, wherein the magnetic encapsulant composite fully encapsulates the solder joint.

18. The package of claim 14, wherein the magnetic encapsulant composite is coupled to the side of the substrate to strengthen the side of the substrate.

19. The package of claim 14, wherein the side of the substrate is a first side of the substrate with a second side opposite the first side; and wherein the second side of the substrate is to couple with a die.

20. The package of claim 19, wherein the package includes the die.
